(19) United States
(12) Patent Application Publication
(10) Pub. No.: US 2013/0286560 A1
(43) Pub. Date: Oct. 31, 2013

(54) BATTERY COVER ASSEMBLY FOR PORTABLE ELECTRONIC DEVICE

(71) Applicant: JUN-FANG LIU, Shenzhen City (CN)

(72) Inventor: JUN-FANG LIU, Shenzhen City (CN)

(21) Appl. No.: 13/664,624

(22) Filed: Oct. 31, 2012

(30) Foreign Application Priority Data
Apr. 25, 2012 (CN) 201210123636.6

(51) Int. Cl. H01M 2/10; H05K 5/00

(52) U.S. Cl. 361/679.01; 429/100

(57) ABSTRACT

A battery cover assembly for a portable electronic device includes a housing and a battery cover. The housing defines two receiving holes and a groove. The battery cover includes two clasps and a resisting sheet, each clasp including an angled portion and a hooked portion connected to each other, the hooked portion extending downwardly, the resisting sheet having a distal end extending upwardly, the clasps latched in the receiving holes and the resisting sheet latched in the groove.

### BACKGROUND

1. Technical Field

The present disclosure generally relates to battery cover assemblies, and particularly to a battery cover assembly for use in a portable electronic device.

2. Description of related art

Batteries are widely used in portable electronic devices, such as personal digital assistants mobile phones, and so on. Conventional batteries are attachably received in the electronic device, and battery covers are designed to connect with housings of the electronic devices to package the batteries. The batteries have to be replaced by opening the battery covers when, for example, the batteries are damaged and/or dead (i.e. no longer rechargeable).

One kind of the battery cover includes conventional hooks made of metal. The hooks are configured for engaging in slots of the housing. However, the metal hooks are easily deformed in daily use. This will make the engagement between the battery cover and the housing of the mobile phone to be loosen so that the assembled battery cover is not stably attached to the housing. More seriously, the deformed metal hooks cannot be assembled in the slots of the housing.

Therefore, there is room for improvement within the art.

### BRIEF DESCRIPTION OF THE DRAWINGS

Many aspects of the battery cover assembly can be better understood with reference to the following drawings. The components in the drawings are not necessarily drawn to scale, the emphasis instead being placed upon clearly illustrating the principles of the battery cover assembly. Moreover, in the drawings, like reference numerals designate corresponding parts throughout the several views.

FIG. 1 is an exploded, isometric view of a portable electronic device employing a battery cover assembly in accordance with an exemplary embodiment.

FIG. 2 is similar to FIG. 1, but viewed from another aspect.

FIG. 3 is an exploded view of the battery cover shown in FIG. 1.

FIG. 4 is a side view of the battery cover in FIG. 2.

FIG. 5 is an assembly view of FIG. 1.

FIG. 6 is an enlarge view of the battery cover assembly of FIG. 5 from another aspect.

### DETAILED DESCRIPTION

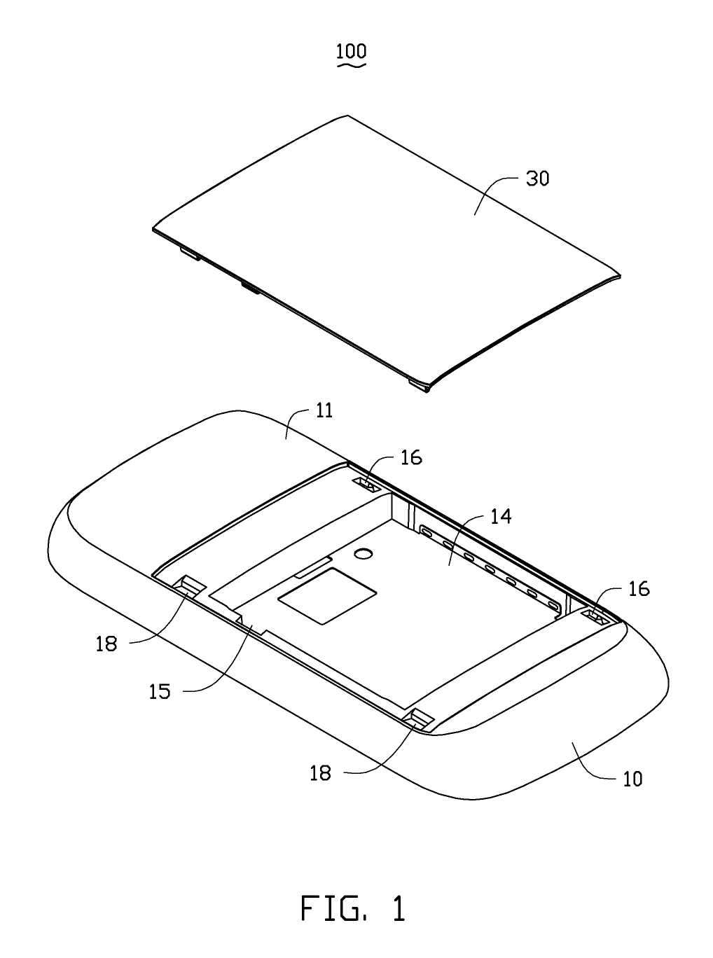

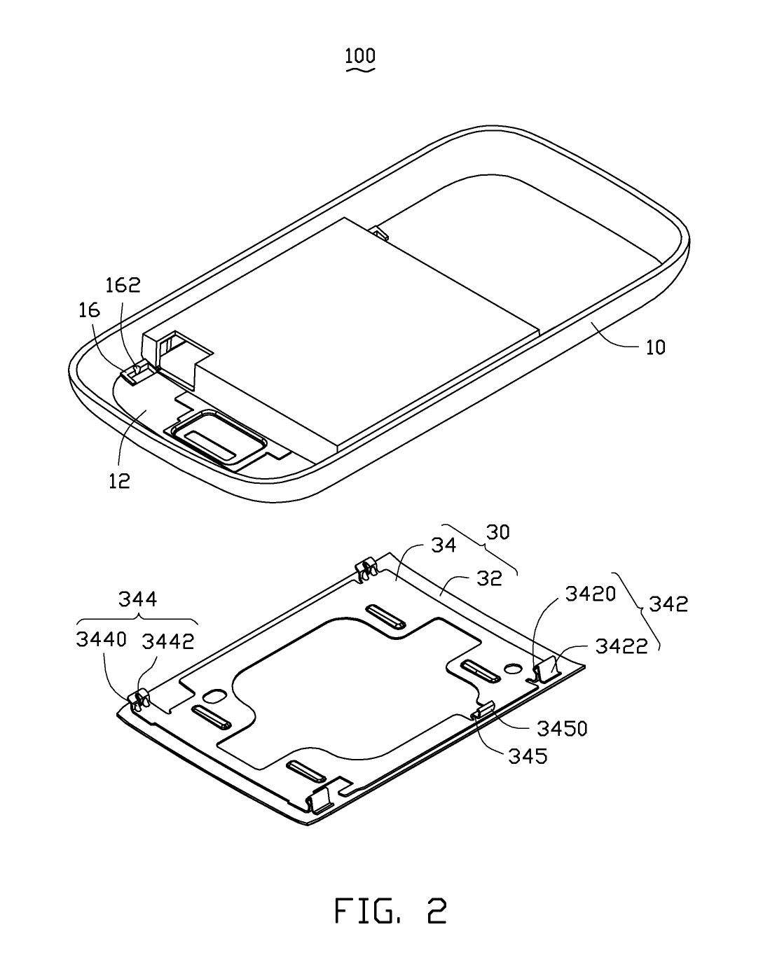

FIGS. 1 and 2 show a portable electronic device 100, such as a mobile phone, employing a battery cover assembly. The mobile phone 100 is an exemplary application, for the purposes of describing details of an exemplary embodiment of a battery cover assembly. The battery cover assembly incorporates a housing 10 and a battery cover 30.

The housing 10 includes a first surface 11 and a second surface 12 opposite to the first surface 11. The first surface 11 defines a receiving cavity 14, configured for receiving a battery, and a groove 15, communicating with the receiving cavity 14. The groove 15 is defined at a boundary of the receiving cavity 14. The first surface 11 defines a pair of latching holes 16 and a pair of receiving holes 18, respectively, at two sides of the receiving cavity 14. The groove 15 is positioned between the receiving holes 18. The second surface 12 defines a positioning notch 162, adjacent to each latching hole 16.

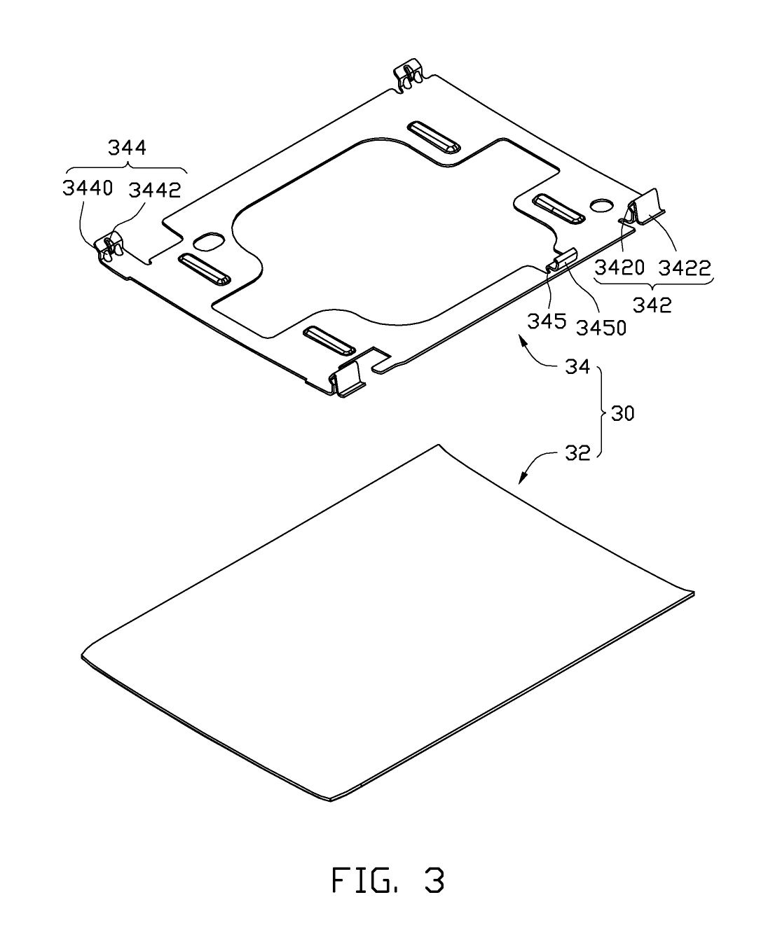

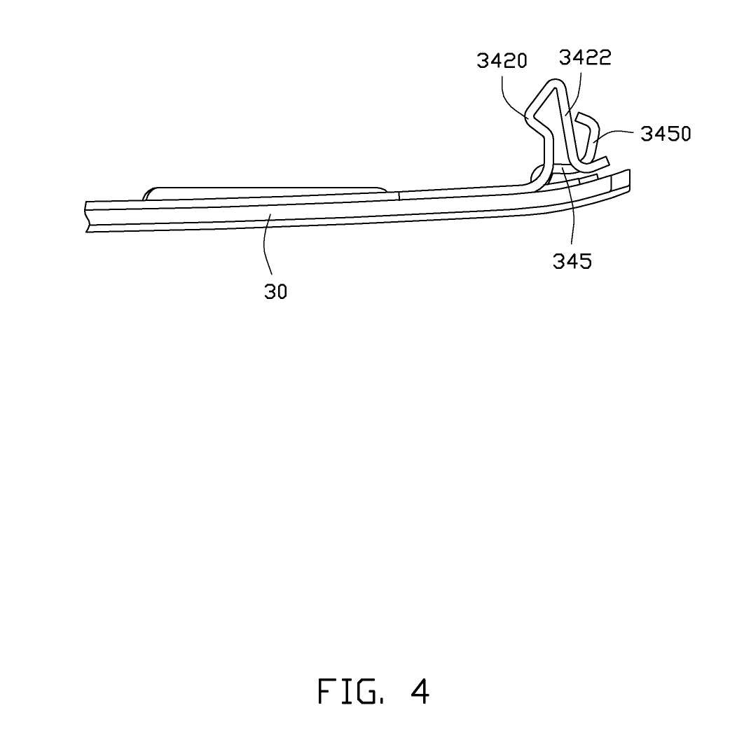

The battery cover 30 is detachably attached to the first surface 11 of the housing 10. Referring to FIGS. 3 and 4, the battery cover 30 includes a main plate 32 and a subsidiary plate 34 attached on the main plate 32. The subsidiary plate 34 is made of metal, and is integrally formed with the main plate 32 by insert molding. [0015] The subsidiary plate 34 includes a pair of clasps 342 and two tabs 344 formed at two opposite edges thereof. A resisting sheet 345 is formed between the two clasps 342. The clasps 342 are engaged in the receiving holes 18, and the tabs 344 are engaged in the latching holes 16. Each clasp 342 includes an angled portion 3420 and a hooked portion 3422 connected to each other. The angled portion 3420 and the hooked portion 3422 are formed by bending a portion of the subsidiary plate 34. The hooked portion 3422 extends downwardly. Each tab 344 includes two reinforcing ribs 3440 and an outwardly projecting arcuate portion 3442 between the ribs 3440. The reinforcing ribs 3440 can improve the strength of the tabs 344. The arcuate portion 3442 is engaged in the positioning notch 162. The resisting sheet 345 includes a distal end 3450 extending upwardly. The extending direction of the distal end 3450 is reverse to the hooked portion 3422.

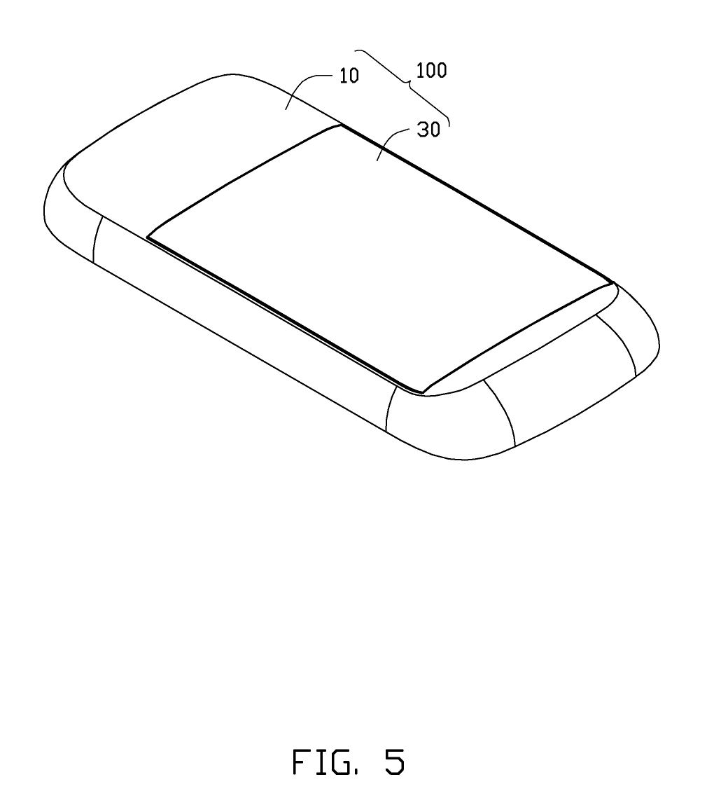

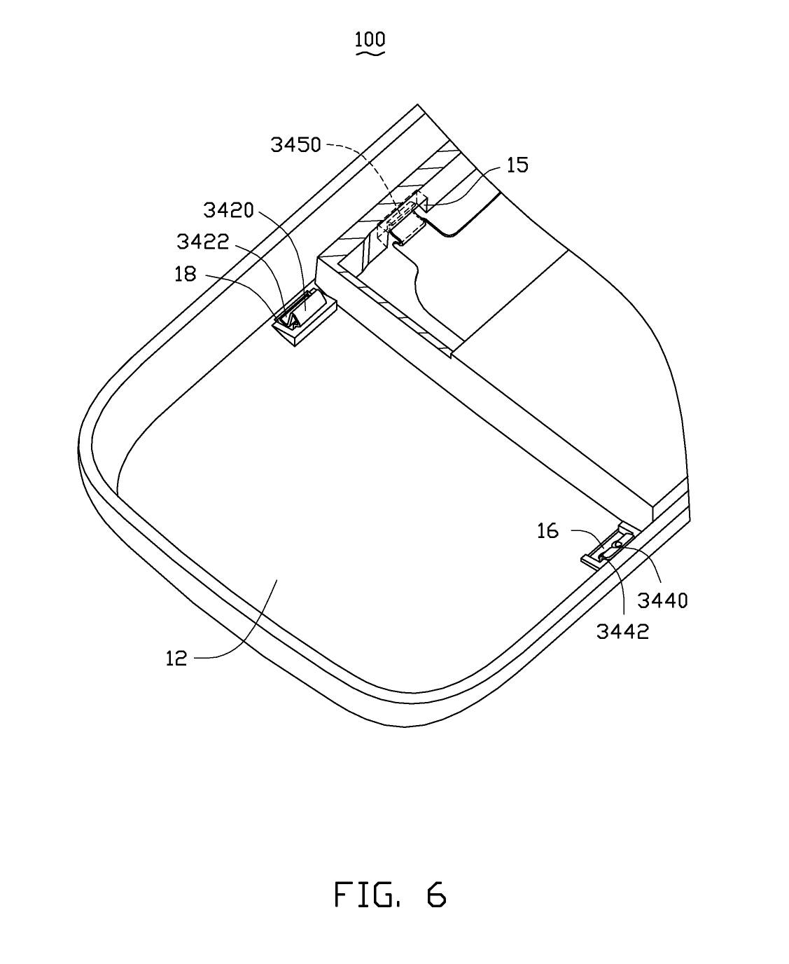

During assembly of the battery cover assembly, referring to FIGS. 5 and 6, one side of the battery cover 30 is attached on the housing 10, and the tabs 344 of the battery cover 30 are firstly engaged in the latching holes 16. The arcuate portion 3442 is engaged in the positioning notch 162. Then, another side of the battery cover 30 is pressed to allow the resisting sheet 345 to be latched in the groove 15. The clasps 342 are engaged in the receiving holes 18. Since the hooked portion 3422 extends downwardly, the hooked portion 3422 can have a supporting and buffering role when the battery cover 30 is applied to an outside force. Additionally, since the extending direction of the distal end 3450 is reverse to the hooked portion 3422, the structure can effectively prevent the clasps 342 from deforming. The assembled battery cover 30 can be stably attached to the housing 10.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

1. A battery cover assembly for a portable electronic device, the battery cover assembly comprising:
a housing defining two receiving holes and a groove;
a battery cover including two clasps and a resisting sheet, each clasp comprising an angled portion and a hooked portion connected to each other; the hooked portion extending downwardly, and the resisting sheet having a distal end extending upwardly; and the two clasps latched in the two receiving holes and the resisting sheet latched in the groove.

2. The battery cover assembly as claimed in claim 1, wherein the battery cover comprises a main plate and a subsidiary plate attached on the main plate, the subsidiary plate is made of metal, and is integrally formed with the main plate.

3. The battery cover assembly as claimed in claim 1, wherein the battery cover comprises two tabs, and the housing defines two latching holes receiving the two tabs.

4. The battery cover assembly as claimed in claim 3, wherein the housing defines a positioning notch, adjacent to each latching hole; each tab comprises two reinforcing ribs and an outwardly projecting arcuate portion between the two reinforcing ribs; and the outwardly projecting arcuate portion is engaged in the positioning notch.

5. A portable electronic device comprising:
a housing defining two receiving holes and two latching holes;
a battery cover comprising two clasps and two tabs, each clasp comprising an angled portion and a hooked portion connected to each other, the hooked portion extending downwardly, the two clasps latched in the two receiving holes, and the two tabs latched in the two latching holes.

6. The portable electronic device as claimed in claim 5, wherein the housing defines a positioning notch adjacent to each latching hole, each tab comprises two reinforcing ribs and an outwardly projecting arcuate portion between the two reinforcing ribs, and the outwardly projecting arcuate portion is engaged in the positioning notch.

7. The portable electronic device as claimed in claim 5, wherein the battery cover comprises a main plate and a subsidiary plate attached on the main plate, the subsidiary plate is made of metal, and is integrally formed with the main plate.
